(19) United States
(12) Patent Application Publication
(10) Pub. No.: US 2006/0247134 A1
(43) Pub. Date: Nov. 2, 2006

(54) Composite conductor with multifilament superconductive strands

(76) Inventors: Nicolas Lallouet, Fiennes (FR); Christian-Eric Bruzek, Thun st martin (FR)

Correspondence Address: SOFER & HAROUN, L.L.P., 317 Madison Avenue , Suite 910, New York, NY, 10017, US

(21) Appl. No.: 11/199,588

(22) Filed: Aug. 8, 2005

(30) Foreign Application Priority Data
Aug. 17, 2004 (FR) 04 51860

(51) Int. Cl. H01L 39/24; H01R 43/00

(52) U.S. Cl. 505/410; 29/599; 505/728; 29/825

(57) ABSTRACT

A composite conductor is provided with multifilament superconductive strands soldered together. The strands are assembled together by a continuous solder joint over their entire length, the solder having a low melting point alloy.

### RELATED APPLICATION

This application is related to and claims the benefit of priority from French Patent Application No. 04 51860, filed on Aug. 17, 2005, the entirety of which is incorporated herein by reference.

### FIELD OF THE INVENTION

The present invention relates to a composite conductor with multifilament superconductive strands intended in particular to be coiled to produce a superconductive magnetic coil.

### BACKGROUND OF THE INVENTION

Making a multifilament superconductive strand in the form of a wire or tape clad in silver is known in the art. The strand is generally fabricated from billets that are filled and drawn, bundled with other billets that are themselves drawn. The resulting multifilament strand can undergo the same steps, and this process can be continued to obtain the required number of filaments per unit area. The drawing operation may be carried out by rolling.

A multifilament strand of the above kind may be coiled to produce a superconductive magnetic coil.

However, such coiling gives rise to the following problems:

Whether it is in the form of a wire or a tape, the multifilament strand is thin and very fragile, and coiling it in a manner that avoids breaking the wire or tape proves to be very difficult. For example, a rolled tape of the above kind may have a width to thickness ratio of the order of 15 to 20.

Moreover, the strand is small, and this implies coiling a certain number of turns to obtain a coil and therefore a relatively great length of multifilament strands and a relatively long coiling time.

U.S. Pat. No. 6,339,047 discloses the production of cables from a plurality of superconductive wires by soldering the wires together.

### OBJECT AND SUMMARY OF THE INVENTION

The object of the present invention is to provide a composite superconductor that solves the above technical problems by means of its relatively large section, this superconductor having strength that makes coiling easier, which coiling can also be carried out with a limited number of turns, thereby optimizing the process.

To this end, the invention proposes a composite conductor with multifilament superconductive strands soldered together, wherein said strands are assembled together by a continuous solder joint over their entire length, the solder joint consisting of a low melting point alloy.

The invention also has the following important advantage. In the event of failure of a multifilament strand of the composite conductor in use, in particular in a magnetic coil, for example through breakage, the current flows to the adjacent strand through the solder joint, regardless of where the failure is located, which assures continuity of current flow. In such circumstances, there is therefore an exchange of current between strands and operation continues, which also makes it possible to shunt the portions of multifilament strands having a lower critical current without limiting the operating point of the coil.

Electrical connections may be made more easily by soldering to the composite conductor which, because of the continuous solder joint, inherently contains the material necessary for soldering.

In a preferred embodiment, said solder joint is obtained by passing said assembled strands into a bath of alloy.

Said alloy is advantageously a tin alloy.

Said strands may consist of Bi2212 filaments in a silver matrix.

In a first embodiment, said strands are flat superconductor tapes.

Said strands are preferably superposed and parallel.

Said composite conductor advantageously includes at least one mechanical reinforcement plate.

In a second embodiment, said strands are cylindrical superconductive wires.

Said wires are preferably laid up around a cylindrical support.

### BRIEF DESCRIPTION OF THE DRAWING

The invention is described in more detail below with the aid of figures representing preferred embodiments of the invention.

FIG. 1 is a view in cross-section of a first embodiment of the invention.

FIG. 2 is a view in cross-section of a second embodiment of the invention.

### MORE DETAILED DESCRIPTION

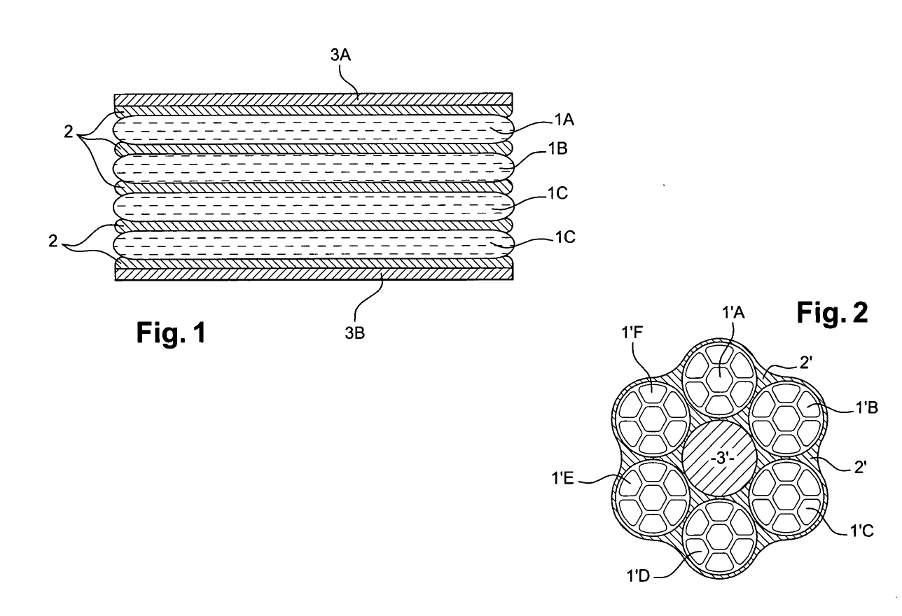

FIG. 1 represents a composite conductor with multifilament superconductive strands 1A to 1C in the form of flat tapes assembled together by a continuous solder joint 2 over their entire length, the solder of the joint 2 consisting of a low melting point alloy. In a preferred embodiment, the tapes 1 consist of Bi2212 filaments in a silver matrix.

The alloy is preferably a tin alloy. An alloy of lead, bismuth, or indium may be used instead.

The tapes 1 are assembled so that they are superposed and parallel and are dipped in a bath of alloy, for example tin alloy, to effect the continuous solder joint and to obtain a sandwich-type composite.

During this dipping in the alloy bath, mechanical reinforcing plates 3A and 3B may also be soldered to the two longitudinal faces of the composite. The plates 3 are made of metal, for example stainless steel or copper alloy.

FIG. 2 shows a composite conductor with multifilament superconductive strands 1′A to 1′F in the form of cylindrical wires assembled together by a solder joint 2′ that is continuous along their entire length, the solder of the joint 2′ consisting of a low melting point alloy. In a preferred embodiment, the tapes 1′ consist of Bi2212 filaments in a silver matrix.

The alloy is preferably a tin alloy. An alloy of lead, bismuth, or indium may be used instead.

The wires 1′ are assembled, laid up about a cylindrical metal support 3′, e.g. made of stainless steel or copper alloy, and dipped in a bath of alloy, for example tin alloy, in order to effect the continuous solder joint and obtain a cylindrical composite.

As is clear from the two preferred embodiments shown, the composite conductor of the invention with multifilament superconductive strands has a section that is four to seven times larger than that of a multifilament strand on its own. Above all, it is mechanically much stronger because of its shape and its composition.

In the case of multifilament tapes, as shown in FIG. 1, the width to thickness ratio of the composite conductor is considerably lower and, being of more compact shape, the conductor is stronger. The mechanical reinforcing plates help to optimize its strength.

In the case of cylindrical wires, as shown in FIGS. 2, a compact, solid structure is obtained in the same way, reinforced by the cylindrical support.

It is therefore easier to manipulate this composite conductor when coiling it in the context of fabricating a magnetic coil, for example. Moreover, in the embodiments shown, the coil may be fabricated more quickly, the number of turns being lower, for example from four to six times lower.

In the event of failure of a multifilament strand when the composite conductor is being used, for example while it is being coiled, current will pass to an adjacent strand through the solder joint, maintaining overall current flow.

Of course, the invention is not limited to the embodiments described and shown, and lends itself to variants that will be within the competence of the person skilled in the art and do not depart from the spirit of the invention. In particular, without departing from the scope of the invention, Bi2212 may be replaced by any other material having the same properties. The shape of the multifilament strands in cross-section may thus be rectangular or round, as shown, but equally a different shape, for example square.

What is claimed is:

1. A composite conductor comprising:
multifilament superconductive strands soldered together, wherein said strands are assembled together by a continuous solder joint over their entire length, the solder joint having a low melting point alloy.

2. A conductor according to claim 1, wherein said solder joint is obtained by passing said assembled strands into a bath of alloy.

3. A conductor according to claim 1, wherein said alloy is a tin alloy.

4. A conductor according to claim 1, wherein said strands are Bi2212 filaments in a silver matrix.

5. A conductor according to claim 1, wherein said strands are flat superconductor tapes.

6. A conductor according to claim 3, wherein said strands are superposed and parallel.

7. A conductor according to claim 5, including a mechanical reinforcement plate.

8. A conductor according to claim 1, wherein said strands are cylindrical superconductive wires.

9. A conductor according to claim 8, wherein said wires are laid up around a cylindrical support.
